(19) United States
(12) Patent Application Publication
(10) Pub. No.: US 2011/0207029 A1
(43) Pub. Date: Aug. 25, 2011

(54) MEDIA FOR VOLUME-HOLOGRAPHIC RECORDING BASED ON SELF-DEVELOPING POLYMER

(75) Inventors: Rainer Hagen, Leverkusen (DE); Nicolas Stoeckel, Koeln (DE); Friedrich-Karl Kruder, Krefeld (DE); Francois Deuber, Koln (DE); Thomas Roelle, Leverkusen (DE); Thomas Faecke, Leverkusen (DE); Marc-Stephan Weiser, Leverkusen (DE); Dennis Hoenel, Zuelpich (DE)

(73) Assignee: BAYER MATERIALSCIENCE AG, Leverkusen (DE)

(21) Appl. No.: 13/121,967

(22) PCT Filed: Sep. 29, 2009
(86) PCT No.: PCT/EP2009/006984

§ 371 Date: May 13, 2011

(30) Foreign Application Priority Data
Oct. 1, 2008 (EP) 08017279.4

(51) Int. Cl. G03F 7/00

(52) U.S. Cl. 430/2

(57) ABSTRACT

The present invention relates to novel self-developing films for incorporation of volume holograms by exposure, a method for production thereof and the use thereof.

The present invention relates to novel self-developing films for incorporation of volume holograms by exposure, a method for the production thereof and the use thereof.

A volume hologram is produced by causing two light waves of the same wavelength, also referred to as object beam and reference beam, to interfere and exposing a holographic recording medium, as a rule a photographic film, to the resulting interference pattern, which as a rule is an intensity pattern. The holographic exposure process and the replication of the hologram are technically complex optical methods which require special knowledge relating to the application. Methods for producing holograms and the theory are described comprehensively in the literature [Howard M. Smith, “Principles of Holography”, Wiley (1969)] [Fred Unterseher, et al. “Holography Handbook: Making Holograms the Easy Way”, Ross Books (1982)] [Graham Saxby, “Practical Holography”, Inst. of Physics Pub. (2004)].

Known recording materials having a different property profile and field of use are: silver halide emulsions, hardened dichromate gelatin, ferroelectric crystals, photochromic and dichriod materials and photopolymers [Howard M. Smith, “Principles of Holography”, Wiley (1969).]. For applications with large quantities, the only materials of interest are those which are present as a stable film prior to exposure and can therefore be integrated without problems into the systems for hologram production and replication and which permit easy holographic exposure and development. Owing to their dry chemistry, the easy handling and their good shelf-life, photopolymers are considered to be particularly preferred. The most well known photopolymers originate from DuPont, e.g. Omnidex HRF 600 [S. M. Schultz, et al. “Volume grating preferential-order focusing waveguide coupler,” Opt. Lett., vol. 24, pp. 1708-1710, December 1999.] Omnidex materials belong to the class consisting of the self-developing photopolymer films based on free radical polymerization and monomer diffusion [EP 0324480].

Omnidex photopolymers were further developed in the course of years, primarily with the aim of increasing the refractive index contrast and of achieving a high diffraction efficiency in the film [U.S. Pat. No. 4,942,112] [DE 69032682]. Nevertheless, the diffraction efficiencies of substantially more than 2/3 which are relevant for applications are achieved by a high proportion of thermoplastic binder and hence a high proportion of solvent, which leads to a considerable, as a rule uncontrolled, decrease on the film thickness in film production. Moreover, the thermal aftertreatment (“annealing”) of the exposed and UV-fixed photopolymer is necessary in order to achieve the maximum refractive index contrast [DE 68905610]. The annealing is an additional processing step which complicates the hologram production and makes it more expensive and moreover limits the choice of the carrier materials to those which are not temperature sensitive.

Other photopolymer materials for volume holography were developed by Polaroid [U.S. Pat. No. 5,759,721], Fuji Photo Film [EP 1510862], Konica Minolta Medical & Graphic [US 2005058911], Dai Nippon Printing [EP 1231511], Nippon Paint [EP 211615], Nissan Chemical Industries [US 20050068594], Xetos [WO 2003036389A] and InPhase Technologies [US 2002142227]. The prior art has photopolymers which differ from Omnidex in their holographic properties or their processing. The technical progress is documented by reduced oxygen sensitivity, reduced material shrinkage during exposure, adapted spectral sensitivity, solvent-free film production, higher diffraction efficiency without annealing and/or better thermal stability and shelf-life.

Photopolymer films which store volume holograms in a lightfast manner and with stability over time must, according to the prior art, be thermally aftertreated and/or show holographic losses caused by absorption, scattering, shrinkage or poor surface quality, which reduces the intensity of the holograms or changes the colour thereof.

True self-developing photopolymer films having a high efficiency and sufficient stability are still a subject of intense research.

It has now surprisingly been found that self-developing photopolymer films having high efficiency and sufficient stability can be obtained precisely when a special combination of carrier material and photopolymer composition based on a matrix which represents a polymeric network and at least one photopolymerizable monomer dissolved therein is used.

The present invention therefore relates to a medium suitable for recording holograms, comprising
I) as a carrier, a stratum of a transparent material or material composite which is transparent to light in the visible spectral range (transmission greater than 85% in the wavelength range of 400 to 780 nm) and may optionally be coated on one or both sides and
II) at least one optionally multilayer photopolymer stratum applied to the carrier I) and based on polyurethane compositions,
   comprising
   A) a polyisocyanate component,
   B) an isocyanate-reactive component,
   C) compounds which have groups reacting under the action of actinic radiation with ethylenically unsaturated compounds with polymerization (radiation-curing groups) and which themselves are free of NCO groups,
   D) photoinitiators
   E) free radical stabilizers
   F) optionally catalysts
   G) optionally auxiliaries and additives.
III) Optionally at least one cover layer on the photopolymer stratum or strata II).

For determining the transparency, the transmission by means of UV/VIS spectrometer, for example from Varian, model spectrophotometer Cary 4G, is used. The measurement is carried out by measuring the material sample in perpendicular incidence in transmission against air. In the context of the present invention, materials or material composites which are regarded as transparent are those for which the transmission is preferably at least 90%, particularly preferably at least 95%.

Actinic radiation is understood as meaning electromagnetic, ionizing radiation, in particular electron beams, UV radiation and visible light (Roche Lexikon Medizin, 4th edition; Urban & Fischer Verlag, Munich 1999).

Preferred materials or material composites of the carrier layer I) are based on polycarbonate (PC), (polyethylene terephthalate (PET), polybutylene terephthalate, polyethylene, polypropylene, cellulose acetate, cellulose hydrate, cellulose nitrate, cycloolefin polymers, polystyrene, polyepoxides, polysulphone, cellulose triacetate (CTA), polyamide, polymethyl methacrylate, polyvinyl chloride, polyvinylbutyral or polydicyclopentadiene or mixtures thereof. Particularly preferably, they are based on PC, PET and CTA.

Material composites may be film laminates or coextrudates. Preferred material composites are duplex and triplex films composed according to one of the schemes A/B, A/B/A or A/B/C. PC/PET, PET/PC/PET and PC/TPU (TPU=thermoplastic polyurethane) are particularly preferred.

As an alternative to the abovementioned plastics carriers, it is also possible to use planar glass plates, which are used in particular for large-area accurately imaging exposures, for example for holographic lithography [Ng, Willie W.; Hong, Chi-Shain; Yariv, Amnon. Holographic interference lithography for integrated optics. IEEE Transactions on Electron Devices (1978), ED-25(10), 1193-1200. ISSN:0018-9383].

Transparent carriers I) which are optically transparent, i.e. not hazy, are preferred. The haze is measurable via the haze value, which is less than 3.5%, preferably less than 1%, particularly preferably less than 0.3%.

The haze value describes the proportion of transmitted light which is scattered in the forward direction by the irradiated sample. Thus, it is a measure of the opacity or haze of transparent materials and quantifies material defects, particles, inhomogeneities or crystalline phase boundaries in the material or its surface which interfere with a clear view through said material. The method for measuring the haze is described in the standard ASTM D 1003.

The carrier I) preferably has a birefringence which is not high, e.g. typically a mean optical retardation of less than 1000 nm, preferably of less than 700 nm, particularly preferably of less than 300 nm.

The retardation R is the mathematical product of the birefringence Δn and the thickness of the carrier d. The automatic and objective measurement of the retardation is effected using an imaging polarimeter, for example from ills GmbH, model StainMatic® M3/M.

The retardation is measured in perpendicular incidence. The retardation values stated for the carrier I) are lateral mean values.

The carrier I), including possibly coatings on one or both sides, typically has a thickness of 5 to 2000 μm, preferably 8 to 200 μm, particularly preferably 10 to 175 μm and in particular 30 to 50 μm.

The materials or material composites of the carrier I) can be treated on one or both sides to make it nontacky, antistatic, water repellent or hydrophilic. The said modifications serve, on the side facing the layer II), to enable the photopolymer stratum II) to be detached without destruction from the carrier I). A modification of that side of the carrier which faces away from the photopolymer stratum serves for ensuring that the media according to the invention meet special mechanical requirements which are necessary, for example, in the processing in roll laminators, in particular in roll-to-roll methods.

The carrier I) can likewise have an antireflective layer, in particular for suppressing undesired interfacial reflections during the holographic exposure.

In a special embodiment which is intended in particular for holding transmission holograms, the carrier I) comprises a reflective layer.

In a further embodiment, the carrier I) comprises on the back an absorbing layer which can be removed without residue and without destruction. This has in particular the function of suppressing undesired reflections from the back during the holographic exposure and can be removed after the end of the holographic exposure so that carrier I) acquires its transparency again. This layer may be present either in the form of a coating or in the form of an essentially stable laminating film. For the laminating film, film materials analogous to the materials used in the carrier layer are preferably used.

In a further embodiment, the carrier I) comprises on one side a scratch-resistant or abrasion-resistant layer. This includes a lamination of the back of the film, for which film materials analogous to the materials used in the carrier layer are preferably used.

The photopolymer strata II) preferably have a total layer thickness, based on all photopolymer strata applied in layer II), of not more than 200 μm, particularly preferably 3 to 200 μm, very particularly preferably 5 to 120 μm and in particular 10 to 30 μm.

The polyurethane compositions of the photopolymer strata II) preferably have a total surface tension which is less than that of the carrier I), including any coatings thereof. The total surface tension is carried out via contact angle measurements with polar and nonpolar measuring liquids, the surface tension of which (polar and nonpolar fraction) is known. According to Owens and Wendt (D. K. Owens and R. C. Wendt, J. Appl. Polym. Sci. 13 (1969), pp. 1741-1747), the nonpolar and polar fraction of the solid surface tension to be determined can be calculated therefrom.

Owing to the lower surface tension, it is possible to achieve layers of the photopolymer strata H) in particular in the abovementioned thickness range and with good surface quality.

Furthermore, this leads to films which can be used in the total visible spectral range (wavelengths 400-800 nm) and are transparent in parts of the near UV range (300-400 nm) and which can be used as photopolymer for the representation of high-contrast holograms in the context of the invention.

The surface tension of the polyurethane compositions is particularly preferably about at least 1 mN/m, very particularly preferably about at least 10 mN/m, in particular about at least 20 mN/m, less than the surface tension of the carrier I).

The isocyanate component A) of the photopolymer stratum preferably comprises polyisocyanates. Polyisocyanates used may be all compounds well known per se to the person skilled in the art or mixtures thereof which have on average two or more NCO functions per molecule. These may have an aromatic, araliphatic, aliphatic or cycloaliphatic basis. Monoisocyanates and/or polyisocyanates containing unsaturated groups may be concomitantly used in minor amounts.

For example, butylene diisocyanate, hexamethylene diisocyanate (HDI), isophorone diisocyanate (IPDI), 1,8-diisocyanato-4-(isocyanatomethyl)octane, 2,2,4- and/or 2,4,4-trimethylhexamethylene diisocyanate, the isomeric bis(4,4′-isocyanatocyclohexyl)methane and mixtures thereof having any desired isomer content, isocyanatomethyl-1,8-octane diisocyanate, 1,4-cyclohexylene diisocyanate, the isomeric cyclohexanedimethylene diisocyanates, 1,4-phenylene diisocyanate, 2,4- and/or 2,6-toluene diisocyanate, 1,5-naphthylene diisocyanate, 2,4′- or 4,4′-diphenylmethane diisocyanate and/or triphenylmethane-4,4′,4″-triisocyanate are suitable.

Also possible is the use of derivatives of monomeric di- or triisocyanates having urethane, urea, carbodiimide, acylurea, isocyanurate, allophanate, biuret, oxadiazinetrione, uretdione and/or iminooxadiazinedione structures.

The use of polyisocyanates based on aliphatic and/or cycloaliphatic di- or triisocyanates is preferred.

The polyisocyanates of component A) are particularly preferably dimerized or oligomerized aliphatic and/or cycloaliphatic di- or triisocyanates.

Isocyanurates, uretdiones and/or iminooxadiazinediones based on HDI, 1,8-diisocyanato-4-(isocyanatomethyl)octane or mixtures thereof are very particularly preferred.

All polyfunctional, isocyanate-reactive compounds which have on average at least 1.5 isocyanate-reactive groups per molecule can be used per se as component B).

Isocyanate-reactive groups in the context of the present invention are preferably hydroxyl, amino or thio groups, hydroxy compounds being particularly preferred.

Suitable polyfunctional, isocyanate-reactive compounds are, for example, polyester polyols, polyether polyols, polycarbonate polyols, poly(meth)acrylate polyols and/or polyurethane polyols.

Suitable polyester polyols are, for example, linear polyester diols or branched polyester polyols, as are obtained in a known manner from aliphatic, cycloaliphatic or aromatic di- or polycarboxylic acids or their anhydrides with polyhydric alcohols having an OH functionality of ≧2.

Examples of such di- or polycarboxylic acids or anhydrides are succinic, glutaric, adipic, pimelic, suberic, azelaic, sebacic, nonanedicarboxylic, decanedicarboxylic, terephthalic, isophthalic, o-phthalic, tetrahydrophthalic, hexahydrophthalic or trimellitic acid and acid anhydrides, such as o-phthalic, trimellitic or succinic anhydride or any desired mixtures thereof with one another.

Examples of such suitable alcohols are ethanediol, di-, tri- and tetraethylene glycol, 1,2-propanediol, di-, tri- and tetrapropylene glycol, 1,3-propanediol, 1,4-butanediol, 1,3-butanediol, 2,3-butanediol, 1,5-pentanediol, 1,6-hexanediol, 2,2-dimethyl-1,3-propanediol, 1,4-dihydroxycyclohexane, 1,4-dimethylolcyclohexane, 1,8-octanediol, 1,10-decanediol, 1,12-dodecanediol, trimethylolpropane, glycerol or any desired mixtures thereof with one another.

The polyester polyols may also be based on natural raw materials, such as castor oil. It is also possible for the polyester polyols to be based on homo- or copolymers of lactones, as can preferably be obtained by an addition reaction of lactones or lactone mixtures, such as butyrolactone, ε-caprolactone and/or methyl-ε-caprolactone, with hydroxy functional compounds such as polyhydric alcohols having an OH functionality of ≧2, for example of the abovementioned type.

Such polyester polyols preferably have number average molar masses of 400 to 8000 g/mol, particularly preferably of 500 to 4000 g/mol. Their OH functionality is preferably 1.5 to 3.5, particularly preferably 1.8 to 3.0.

Suitable polycarbonate polyols are obtainable in a manner known per se by reacting organic carbonates of phosgene with diols or diol mixtures.

Suitable organic carbonates are dimethyl, diethyl and diphenyl carbonate.

Suitable diols or mixtures comprise the polyhydric alcohols mentioned per se in connection with the polyester segments and having an OH functionality of ≧2, preferably 1,4-butanediol, 1,6-hexanediol and/or 3-methylpentanediol, or polyester polyols can be converted into polycarbonate polyols.

Such polycarbonate polyols preferably have number average molar masses of 400 to 4000 g/mol, particularly preferably of 500 to 2000 g/mol. The OH functionality of these polyols is preferably 1.8 to 3.2, particularly preferably 1.9 to 3.0.

Suitable polyether polyols are polyadduct cyclic ethers with OH- or NH-functional initiator molecules, which polyadducts optionally have a block structure.

Suitable cyclic ethers are, for example, styrene oxides, ethylene oxide, propylene oxide, tetrahydrofuran, butylene oxide, epichlorohydrin and any desired mixtures thereof.

The polyhydric alcohols mentioned in connection with the polyester polyols and having an OH functionality of ≧2 and primary or secondary amines and amino alcohols can be used as initiators.

Such polyether polyols preferably have number-average molar masses of 250 to 10 000 g/mol, particularly preferably of 500 to 8500 g/mol and very particularly preferably of 600 to 4500 g/mol. The OH functionality is preferably 1.5 to 4.0, particularly preferably 1.8 to 3.0.

In addition, aliphatic, araliphatic, cycloaliphatic di-, tri- or polyfunctional alcohols which have a low molecular weight, i.e. having molecular weights less than 500 g/mol, and have short chains, i.e. contain 2 to 20 carbon atoms, are also suitable as constituents of component B), as polyfunctional, isocyanate-reactive compounds.

These may be, for example, ethylene glycol, diethylene glycol, triethylene glycol, tetraethylene glycol, dipropylene glycol, tripropylene glycol, 1,2-propanediol, 1,3-propanediol, 1,4-butanediol, neopentyl glycol, 2-ethyl-2-butylpropanediol, trimethylpentanediol, diethyloctanediol positional isomers, 1,3-butylene glycol, cyclohexanediol, 1,4-cyclohexanedimethanol, 1,6-hexanediol, 1,2- and 1,4-cyclohexanediol, hydrogenated bisphenol A (2,2-bis(4-hydroxycyclohexyl)propane), 2,2-dimethyl-3-hydroxypropyl 2,2-dimethyl-3-hydroxypropionate. Examples of suitable triols are trimethylolethane, trimethylolpropane or glycerol. Suitable higher-functional alcohols are ditrimethylolpropane, pentaerythritol, dipentaerythritol or sorbitol.

Preferred components B) are poly(propylene oxides), poly(ethylene oxides) and combinations thereof in the form of random or block copolymers and block copolymers of propylene oxide and/or ethylene oxide, which additionally contain tetrahydrofuran, butylene oxide or ε-caprolactone as monomer units and mixtures thereof having an OH functionality of 1.5 to 6 and a number average molar mass between 200 and 18 000 g/mol, particularly preferably having an OH functionality of 1.8 to 4.0 and a number average molar mass between 600 and 8000 g/mol and very particular preferably having an OH functionality of 1.9 to 3.1 and a number average molar mass between 650 and 4500 g/mol.

In component C), compounds such as α,β-unsaturated carboxylic acid derivatives, such as acrylates, methacrylates, maleates, fumarates, maleimides, acrylamides, and furthermore vinyl ether, propenyl ether, allyl ether and compounds containing dicyclopentadienyl units and olefinically unsaturated compounds, such as, for example, styrene, α-methylstyrene, vinyltoluene, olefinins, such as, for example, 1-octene and/or 1-decene, vinyl esters, (meth)acrylonitrile, (meth)acrylamide, methacrylic acid, acrylic acid. Acrylates and methacrylates are preferred.

In general, esters of acrylic acid or methacrylic acid are referred to as acrylates or methacrylates. Examples of acrylates and methacrylates which can be used are methyl acrylate, methyl methacrylate, ethyl acrylate, ethyl methacrylate, ethoxyethyl acrylate, ethoxyethyl methacrylate, n-butyl acrylate, n-butyl methacrylate, tert.-butyl acrylate, tert-butyl methacrylate, hexyl acrylate, hexyl methacrylate, 2-ethylhexyl acrylate, 2-ethylhexyl methacrylate, butoxyethyl acrylate, butoxyethyl methacrylate, lauryl acrylate, lauryl methacrylate, isobornyl acrylate, isobornyl methacrylate, phenyl acrylate, phenyl methacrylate, p-chlorophenyl acrylate, p-chlorophenyl methacrylate, p-bromophenyl acrylate, p-bromophenyl methacrylate, 2,4,6-trichlorophenyl acrylate, 2,4,6-trichlorophenyl methacrylate, 2,4,6-tribromophenyl acrylate, 2,4,6-tribromophenyl methacrylate, pentachlorophenyl acrylate, pentachlorophenyl methacrylate, pentabromophenyl acrylate, pentabromophenyl methacrylate, pentabromobenzyl acrylate, pentabromobenzyl methacrylate, phenoxyethyl acrylate, phenoxyethyl methacrylate, phenoxyethoxyethyl acrylate, phenoxyethoxyethyl methacrylate, 2-naphthyl acrylate, 2-naphthyl methacrylate, 1,4-bis(2-thionaphthyl)-2-butyl acrylate, 1,4-bis(2-thionaphthyl)-2-butyl methacrylate, propane-2,2-diylbis[(2,6-dibromo-4,1-phenylene)oxy(2-{[3,3,3-tris(4-chlorophenyl)propanoyl]oxy}propane-3,1-diyl)oxyethan-2,1-diyl]diacrylate, bisphenol A diacrylate, bisphenol A dimethacrylate, tetrabromobisphenol A diacrylate, tetrabromobisphenol A dimethacrylate and the ethoxylated analogue compounds thereof, N-carbazolyl acrylates, to mention but a selection of acrylates and methacrylates which can be used.

Of course, urethane acrylates can also be used as component C). Urethane acrylates are understood as meaning compounds having at least one acrylic ester group which additionally has at least one urethane bond. It is known that such compounds can be obtained by reacting a hydroxy functional acrylate with an isocyanate-functional compound.

Examples of isocyanates which can be used for this purpose are aromatic, araliphatic, aliphatic and cycloaliphatic di-, tri- or polyisocyanates. It is also possible to use mixtures of such di-, tri- or polyisocyanates. Examples of suitable di-, tri- or polyisocyanates are butylene diisocyanate, hexamethylene diisocyanate (HDI), isophorone diisocyanate 1,8-diisocyanato-4-(isocyanatomethyl)octane, 2,2,4- and/or 2,4,4-trimethylhexamethylene diisocyanate, the isomeric bis(4,4′-isocyanatocyclohexyl)methanes and mixtures thereof having any desired isomer content, isocyanatomethyl-1,8-octane diisocyanate, 1,4-cyclohexylene diisocyanate, the isomeric cyclo-hexanedimethylene diisocyanates, 1,4-phenylene diisocyanate, 2,4- and/or 2,6-toluene diisocyanate, 1,5-naphthylene diisocyanate, 2,4′- or 4,4′-diphenylmethane diisocyanate, 1,5-naphthylene diisocyanate, triphenylmethane-4,4′,4″-triisocyanate and tris(p-isocyanatophenyl) thiophosphate or derivatives thereof having a urethane, urea, carbodiimide, acylurea, isocyanurate, allophanate, biuret, oxadiazinetrione, uretdione or iminooxadiazinedione structure and mixtures thereof. Aromatic or araliphatic di-, tri- or polyisocyanates are preferred.

Suitable hydroxy functional acrylates or methacrylates for the preparation of urethane acrylates are, for example, compounds such as 2-hydroxyethyl(meth)acrylate, polyethylene oxide mono(meth)acrylates, polypropylene oxide mono(meth)acrylates, polyalkylene oxide mono-(meth)acrylates, poly(ε-caprolactone) mono(meth)acrylates, such as, for example, Tone® M100 (Dow, Schwalbach, Germany), 2-hydroxypropyl(meth)acrylate, 4-hydroxybutyl(meth)acrylate, 3-hydroxy-2,2-dimethylpropyl(meth)acrylate, hydroxypropyl(meth)acrylate, 2-hydroxy-3-phenoxy propyl acrylate, the hydroxy functional mono-, di- or tetraacrylates of polyhydric alcohols, such as trimethylolpropane, glycerol, pentaerythritol, dipentaerythritol, ethoxylated, propoxylated or alkoxylated trimethylolpropane, glycerol, pentaerythritol, dipentaerythritol or industrial mixtures thereof. 2-Hydroxyethyl acrylate, hydroxypropyl acrylate, 4-hydroxybutyl acrylate and poly(c-caprolactone) mono(meth)acrylates are preferred. In addition, are suitable isocyanate-reactive oligomeric or polymeric unsaturated compounds containing acrylate and/or methacrylate groups, alone or in combination with the abovementioned monomeric compounds. The epoxy (meth)acrylates known per se, containing hydroxyl groups and having OH contents of 20 to 300 mg KOH/g or polyurethane(meth)acrylates containing hydroxyl groups and having OH contents of 20 to 300 mg KOH/g or acrylated polyacrylates having OH contents of 20 to 300 mg KOH/g and mixtures thereof with one another and mixtures with unsaturated polyesters containing hydroxyl groups and mixtures with polyester(meth)acrylates or mixtures of unsaturated polyesters containing hydroxyl groups with polyester(meth)acrylates can also be used. Epoxy acrylates containing hydroxyl groups and having a defined hydroxyl functionality are preferred. Epoxy (meth)acrylates containing hydroxyl groups are based in particular on reaction products of acrylic acid and/or methacrylic acid with epoxides (glycidyl compounds) with monomeric, oligomeric or polymeric bisphenol A, bisphenol F, hexanediol and/or butanediol or the ethoxylated and/or propoxylated derivatives thereof. Epoxy acrylates having a defined functionality, as can be obtained from the known reaction of acrylic acid and/or methacrylic acid and glycidyl(meth)acrylate, are furthermore preferred.

Compounds having vinyl ether, acrylate or methacrylate groups, particularly preferably acrylate and/or methacrylate groups, are preferably used in component C).

Compounds of the abovementioned type having a refractive index greater than 1.55, particularly preferably 1.58, are preferably used in C).

In a particularly preferred embodiment of the invention, the writing monomer component C) comprises one or more compounds of the formulae (I) to (III):

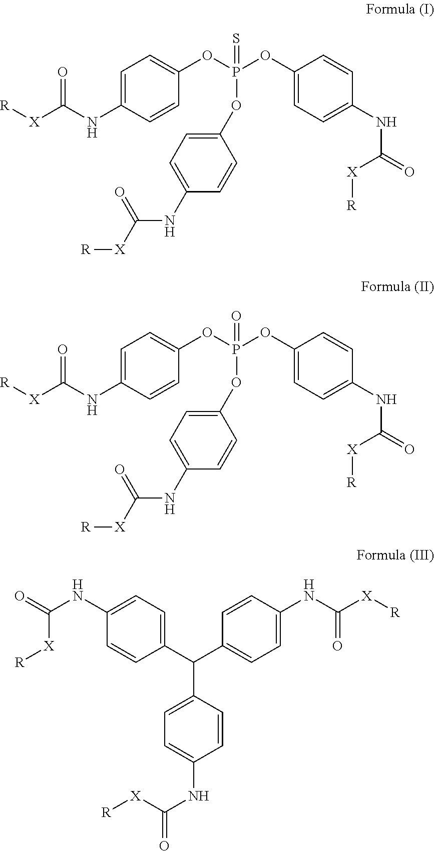

in which
R independently of one another, are in each case a radiation-curable group and
X independently of one another, are in each case a single bond between R and C═O or a linear, branched or cyclic optionally heteroatom-containing hydrocarbon radical and/or hydrocarbon radical optionally substituted by functional groups.

R is preferably a vinyl ether, acrylate or methacrylate group, particularly preferably an acrylate group.

In principle, individual carbon-bonded hydrogen atoms or a plurality of the carbon-bonded hydrogen atoms of the group R can also be replaced by C₁- to C₅-alkyl groups, which however is not preferred.

The group X preferably has 2 to 40 carbon atoms and one or more oxygen atoms present in the form of ether bridges. X may be either linear or branched or cyclic or substituted by functional groups. Particularly preferably, the group X is in each case a linear or branched oxyalkylene or polyoxyalkylene group.

Preferred polyoxyalkylene groups have up to 10, preferably up to 8, repeating units of the respective oxyalkylene groups.

In principle, it is possible for X to have identical or different oxyalkylene groups as repeating units, one such repeating unit preferably having 2 to 6, particularly preferably 2 to 4, carbon atoms. Particularly preferred oxyalkylene units are oxyethylene and in each case the isomeric oxypropylenes or oxybutylenes.

The repeating units within the respective group X may be present completely or partly distributed blockwise or randomly.

In a preferred embodiment of the invention, X, independently of one another, are in each case an oxyalkylene unit selected from the group consisting of —CH₂—CH₂—O—, —CH₂—CHCH₃—O—, —CHCH₃—CH₂—O—, —(CH₂—CH₂—O)ₙ—, —O(CH₂—CHCH₃—O)ₙ—, where n is an integer from 2 to 7, and —O—CH₂—CH₂—(O—(CH₂)₅—CO)ₘ—, where m is an integer from 1 to 5.

One or more photoinitiators are used as component D). These are usually initiators which can be activated by actinic radiation and which initiate a polymerization of the corresponding polymerizable groups. Photoinitiators are commercially sold compounds known per se, a distinction being made between monomolecular (type I) and bimolecular (type II) initiators. Furthermore, these initiators are used for free radical, anionic (or) cationic (or mixed) forms of the abovementioned polymerizations, depending on the chemical nature.

(Type I) systems for the free radical photopolymerization are, for example, aromatic ketone compounds, e.g. benzophenones, in combination with tertiary amines, alkylbenzophenones, 4,4′-bis(dimethylamino)benzophenone (Michler's ketone), anthrone and halogenated benzophenones or mixtures of the said types. Furthermore suitable are (type II) initiators, such as benzoin and its derivatives, benzil ketals, acylphosphine oxides, e.g. 2,4,6-trimethyl-benzoyldiphenylphosphine oxide, bisacylophosphine oxide, phenylglyoxylic esters, camphorquinone, alpha-aminoalkylphenone, alpha-,alpha-dialkoxyacetophenone, 1-[4-(phenylthio)phenyl]octane-1,2-dione 2-(O-benzoyloxime) and alpha-hydroxyalkylphenone. The photoinitiator systems described in EP-A 0223587 and consisting of a mixture of ammonium arylborate and one or more dyes can also be used as a photoinitiator. For example, tetrabutylammonium triphenylhexylborate, tetrabutylammonium tris-(3-fluorophenyl)hexylborate and tetrabutylammonium tris-(3-chloro-4-methylphenyl)hexylborate are suitable as the ammonium arylborate. Suitable dyes are, for example, new methylene blue, thionine, Basic Yellow, pinacynol chloride, rhodamine 6G, gallocyanine, ethyl violet, Victoria Blue R, Celestine Blue, Quinaldine red, crystal violet, brilliant green, astrazon orange G, darrow red, pyronin Y, Basic Red 29, pyrillium I, cyanine and methylene blue, azure A (Cunningham et al., RadTech '98 North America UV/EB Conference Proceedings, Chicago, Apr. 19-22, 1998).

The photoinitiators used for the anionic polymerization are as a rule (type I) systems and are derived from transition metal complexes of the first row. Chromium salts, such as, for example, trans-Cr(NH₃)₂(NCS)₄⁻ (Kutal et al, Macromolecules 1991, 24, 6872) or ferrocenyl compounds (Yamaguchi et al. Macromolecules 2000, 33, 1152) are known here. A further possibility of the anionic polymerization consists in the use of dyes such as crystal violet leuconitrile or malachite green, which can polymerize cyanoacrylates by photolytic decomposition (Neckers et al. Macromolecules 2000, 33, 7761). However, the chromophore is incorporated into the polymer so that the resulting polymers are coloured through.

The photoinitiators used for the cationic polymerization substantially comprise three classes: aryldiazonium salts, onion salts (here specifically: iodonium, sulphonium and selenonium salts) and organometallic compounds. Under irradiation both in the presence and in the absence of a hydrogen donor, phenyldiazonium salts can produce a cation that initiates the polymerization. The efficiency of the total system is determined by the nature of the counterion used for the diazonium compound. Slightly reactive but very expensive SbF₆⁻, AsF₆⁻ or PF₆⁻ are preferred here. For use in coating thin films, these compounds are as a rule not very suitable since the surface quality is reduced by the nitrogen liberated after the exposure (pinholes) (Li et al., Polymeric Materials Science and Engineering, 2001, 84, 139). Very widely used and also commercially available in many types of forms are onium salts, especially sulphonium and iodonium salts. The photochemistry of these compounds has been investigated for a long time. The iodonium salts initially decompose homolytically after excitation and thus produce a free radical and a free radical cation to stabilize by H abstraction, liberates a proton and then initiates the cationic polymerization (Dektar et al. J. Org. Chem. 1990, 55, 639; J. Org. Chem., 1991, 56, 1838). This mechanism permits the use of iodonium salts also for the free radical photopolymerization. The choice of the counterion was very important here; the very expensive SbF₆⁻, AsF₆⁻ or PF₆⁻ are likewise preferred. Otherwise, in this structure class, the choice of the substitution of the aromatic is quite free and is determined substantially by the availability of suitable starting building blocks for the synthesis. The sulphonium salts are compounds which decompose according to Norrish(II) (Crivello et al., Macromolecules, 2000, 33, 825). In the case of the sulphonium salts, too, the choice of the counterion is of critical importance, which manifests itself substantially in the curing rate of the polymers. The best results are obtained as a rule with SbF₆⁻ salts. Since the self-absorption of iodonium and sulphonium salts is at <300 nm, these compounds must be appropriately sensitized for the photopolymerization with near UV or short-wave visible light. This is achieved by the use of more highly absorbing aromatics, such as, for example, anthracene and derivatives (Gu et al., Am. Chem. Soc. Polymer Preprints, 2000, 41 (2), 1266) or phenothiazine or derivatives thereof (Hua et al, Macromolecules 2001, 34, 2488-2494).

It may also be advantageous to use mixtures of these compounds. Depending on the radiation source used for the curing, the type and concentration of photoinitiator must be adapted in a manner known to the person skilled in the art. The abovementioned configuration with regard to the photopolymerization is easily possible for a person skilled in the art in the form of routine experiments within the below-mentioned quantity ranges of the components and the synthesis components available for choice in each case, in particular the preferred synthesis components.

Preferred photoinitiators D) are mixtures of tetrabutylammonium tetrahexylborate, tetrabutylammonium triphenylhexylborate, tetrabutylammonium tris(3-fluorophenyl)hexylborate and tetrabutylammonium tris(3-chloro-4-methylphenyl)hexylborate with dyes, such as, for example, astrazon orange G, methylene blue, new methylene blue, azure A, pyrillium I, safranine O, cyanine, gallocyanine, brilliant green, crystal violet, ethyl violet and thionine.

Furthermore, in addition to the components A) to C), the formulations according to the invention can also be used free radical stabilizers, catalysts and further additives with.

Suitable free radical stabilizers E) are inhibitors and antioxidants, as described in “Methoden der organischen Chemie [Methods in Organic Chemistry]” (Houben-Weyl), 4th edition, Volume XIV/1, page 433 et sec., Georg Thieme Verlag, Stuttgart 1961. Suitable classes of substances are, for example, phenols, such as, for example, 2,6-di-tert-butyl-4-methylphenol, cresols, hydroquinones, benzyl alcohols, such as, for example, benzhydrol, optionally also quinones, such as, for example, 2,5-di-tert-butylquinone, optionally also aromatic amines, such as diisopropylamine or phenothiazine. Preferred free radical stabilizers are 2,6-di-tert-butyl-4-methylphenol, phenothiazine and benzhydrol.

Furthermore, one or more catalysts F) can be used. These preferably catalyse the urethane formation. Amines and metal compounds of the metals tin, zinc, iron, bismuth, molybdenum, cobalt, calcium, magnesium and zirconium are preferably suitable for this purpose. Tin octanoate, zinc octanoate, dibutyltin dilaurate, dimethyltin dicarboxylate, iron(III)acetylacetonate, iron(II)chloride, zinc chloride, tetraalkylammonium hydroxides, alkali metal hydroxides, alkali metal alcoholates, alkali metal salts of long-chain fatty acids having 10 to 20 carbon atoms and optionally OH side groups, lead octanoate or tertiary amines, such as triethylamine, tributylamine, dimethylbenzylamine, dicyclohexylmethylamine, dimethylcyclohexylamine, N,N,N′,N′-tetra-methyldiaminodiethyl ether, bis(dimethylaminopropyl)urea, N-methyl- or N-ethylmorpholine, N,N′-dimorpholinodiethyl ether (DMDEE), N-cyclohexylmorpholine, N,N,N′,N′-tetramethyl-ethylenediamine, N,N,N′,N′-tetramethylbutanediamine, N,N,N′,N′-tetramethylhexane-1,6-diamine, pentamethyldiethylenetriamine, dimethylpiperazine, N-dimethylaminoethylpiperidine, 1,2-dimethylimidazole, N-hydroxypropylimidazole, 1-azabicyclo[2.2.0]octane, 1,4-diazabicyclo-[2.2.2]octane (DABCO) or alkanolamine compounds, such as triethanolamine, triisopropanolamine, N-methyl- and N-ethyldiethanolamine, dimethylaminoethanol, 2-(N,N-dimethylaminoethoxy)ethanol or N-tris(dialkylaminoalkyl)hexahydrotriazines, e.g. N,N′,N-tris(dimethylaminopropyl)-s-hexahydrotriazine, 1,4-diazabicyclo[2.2.2]octane, diazabicyclononane, diazabicycloundecane, 1,1,3,3-tetramethylguanidine, 1,3,4,6,7,8-hexahydro-1-methyl-2H-pyrimido(1,2-a)pyrimidine are particularly preferred.

Particularly preferred catalysts are dibutyltin dilaurate, dimethyltin dicarboxylate, iron(III)acetylacetonate, 1,4-diazabicyclo[2.2.2]octane, diazabicyclononane, diazabicycloundecane, 1,1,3,3-tetramethylguanidine, 1,3,4,6,7,8-hexahydro-1-methyl-2H-pyrimido(1,2-a)pyrimidine.

For example, solvents, plasticizers, levelling agents, wetting agents, antifoams or adhesion promoters, but also polyurethanes, thermoplastic polymers, oligomers, compounds having further functional groups, such as, for example, acetals, epoxide, oxetanes, oxazolines, dioxolanes and/or hydrophilic groups, such as, for example, salts and/or polyethylene oxides, may be present as further auxiliaries and additives G).

Readily volatile solvents having good compatibility with the formulations essential for the invention, for example, ethyl acetate, butyl acetate, acetone, are preferably used as solvents.

Liquids having good dissolution properties, low volatility and a high boiling point are preferably used as plasticizers.

It may also be advantageous simultaneously to use a plurality of additives of one type. Of course, a plurality of additives or a plurality of types can also advantageously be used.

In addition to the constituents I) and II), the media according to the invention may have one or more cover layers III) on the photopolymer stratum or strata II) in order to protect them from dirt and environmental influences. Plastics films or film composite systems, but also clearcoats or planar glass plates, can be used for this purpose.

Film materials analogous to the materials used in the carrier layer are preferably used as cover layers III), these a thickness of typically 5 to 200 μm, preferably 8 to 125 μm, particularly. preferably 10 to 50 μm.

Cover layers III) having as smooth a surface as possible are preferred. The roughness determined according to DIN EN ISO 4288 “Geometrical Product Specification (GPS)—Surface Texture . . . ”, test condition R3z front and back, is considered to be a measure. Preferred roughnesses are in the range of less than or equal to 2 μm, preferably less than or equal to 0.5 μm.

If the cover layers III) are optically transparent for the light source which is used in the holographic exposure process, i.e. show high transmittances of typically greater than 80%, they can be applied to the medium according to the invention even before the holographic exposure and can remain in the medium even during the holographic exposure. If they are not transparent, the holographic coating must as a rule be effected without the cover layers III). The medium according to the invention is then to be provided with the nontransparent cover layer after the holographic exposure.

The method for determining the transparency is described above.

A preferred embodiment of the medium according to the invention is the transfer film composite in which the photopolyrner stratum or strata (II) can be transferred to other surfaces, in particular in industrial manufacturing methods, such as roll-to-roll methods using lamination, adhesion or another joining technique.

Said embodiment is characterized in that the cover layer III) consisting of a plastics film or a film composite system can be removed over the whole surface with application of little force from the photopolyrner stratum or strata II). The adhesive bond between carrier film I) and photopolymer stratum/photopolymer strata is somewhat stronger than that between photopolymer stratum/photopolymer strata II) and cover layer III), so that photopolymer stratum/photopolyrner strata II) remain completely and without destruction on the carrier film I) on said removal of the cover layer III).

The transferring of the photopolymer stratum or strata is effected in individual steps as follows: first, the cover layer III) is removed from the medium. Thereafter, this composite with the open photopolymer stratum can be transferred to any other surfaces. In particular, this film composite is distinguished firstly by the highest possible adhesion between photopolymer and carrier film I) in order to ensure a stable film composite, but secondly by the lowest possible adhesion so that this carrier film can be removed after the lamination or adhesion process and the photopolymer remains without destruction on the new surface.

The present invention furthermore relates to a method for the production of the media according to the invention suitable for recording holograms, in which one or more photopolymer strata II) having the composition described above are placed on a carrier I) and are applied and cured.

The components A) and B) are used in an OH/NCO ratio to one another of typically 0.5 to 2.0, preferably 0.95 to 1.50, particularly preferably 0.97 to 1.33.

The method according to the invention is preferably carried out in such a way that the synthesis components of the polyurethane composition essential to the invention, with the exception of the component A), are homogeneously mixed with one another and the component A) is admixed immediately before application to the substrate or in the mould.

All methods and apparatuses known per se to the person skilled in the art from mixing technology, such as, for example, stirred tanks of both dynamic and static mixers, can be used for the mixing. However, apparatuses without dead spaces or with only small dead spaces are preferred. Furthermore, methods in which the mixing is effected within a very short time and with very thorough mixing of the two components to be mixed are preferred. In particular, dynamic mixers, especially those in which the components come into contact with one another only in the mixer, are suitable for this purpose.

The temperatures during this procedure are 0 to 100° C., preferably 10 to 80° C., particularly preferably 20 to 60° C., very particularly preferably 20 to 40° C.

If necessary, the degassing of the individual components or of the total mixture under reduced pressure of, for example, 1 mbar can also be carried out. Degassing, in particular, after addition of the component A), is preferred in order to prevent bubble formation through residual gases in the media obtainable.

Prior to admixing of the component A), the mixtures can be stored as a storage-stable intermediate, if required over several months.

The admixing of the component A) gives a clear, liquid formulation which cures within a few seconds to a few hours, at room temperature, depending on the composition.

The ratio and the type and reactivity of synthesis components is preferably set so that the curing after the admixing of component A) occurs within minutes to an hour at room temperature. In a preferred embodiment, the curing is accelerated by heating the formulation after the admixing to temperatures between 30 and 180° C., preferably 40 to 120° C., particularly preferably 50 to 100° C.

The abovementioned configuration with regard to the curing behaviour is easily possible for the person skilled in the art easily in the form of routine experiments within the abovementioned quantity range of components and the synthesis components available for choice in each case, in particular the preferred synthesis components.

Immediately after complete mixing of all components, the polyurethane compositions essential to the invention have viscosities at 25° C. of typically 10 to 100 000 mP·as, preferably 100 to 20 000 mP·as, particularly preferably 200 to 15 000 mP·as, especially preferably 500 to 10 000 mP·as, so that they have very good processing properties even in solvent-free form. In solution with suitable solvents, viscosities at 25° C. below 10 000 mP·as, preferably below 2000 mP·as, particularly preferably below 500 mP·as, can be established.

Polyurethane compositions of the abovementioned type which, in an amount of 15 g and having a catalyst content of 0.004% by weight, cure at 25° C. in less than 4 hours or, in the case of a catalyst content of 0.02%, cure in less than 10 minutes at 25° C. have proved to be advantageous.

All respective customary methods known to the person skilled in the art, such as, in particular, knifecoating, casting, printing, screenprinting, spraying or inkjet printing, are suitable for application to the carrier I).

Holograms for optical applications in the entire visible range, including the near IJV range (total wavelength window 300-800 nm), can be produced on the media according to the invention by corresponding exposure processes. Visual holograms comprise all holograms which can be recorded by methods known to persons skilled in the art, including, inter alia, in-line (Gabor) holograms, off-axis holograms, full-aperture transfer holograms, white light transmission holograms (“rainbow holograms”), Denisyuk holograms, off-axis reflection holograms, edge-lit holograms and holographic stereograms; reflection holograms, Denisyuk holograms and transmission holograms are preferred.

Such holograms are suitable for personalized data, such as portraits, biometric and other machine-readable information and digital data in security documents, or generally for the representation of images or image structures for advertising, security labels, trademark protection, trademark branding, labels, design elements, decorations, illustrations, multi-journey tickets, images and the like and images which can represent digital data, inter alia also in combination with the products described above. Holographic images may give the impression of a three-dimensional image but they may also represent image sequences, short films or a number of different objects, depending from which angle and with which light source (including moving light source), etc it is illuminated. Owing to these varied design possibilities, holograms, in particular volume holograms, are an attractive technical solution for the abovementioned application.

The production of optical elements, such as lenses, mirrors, deflection mirrors, filters, diffusion screens, diffraction elements (e.g. holographic-optical elements), light guides, waveguides (e.g. holographic diffraction gratings), projection screens and/or photo masks/plates, have is also likewise possible. Frequently, these optical elements show a frequency selectivity, depending on how the holograms were illuminated and on the dimensions of the hologram.

### EXAMPLES

The following examples are mentioned for illustrating the photopolymers according to the invention but are not intended to be understood as being limiting. Unless noted otherwise, all stated percentages are based on percent by weight.

Starting Materials:

Preparation of the Urethane Acrylate (Component C)

0.1 g of 2,6-di-tert-butyl-4-methylphenol, 0.05 g of dibutyltin dilaurate (Desmorapid Z, Bayer MaterialScience AG, Leverkusen, Germany) and and 213.07 g of a 27% strength solution of tris(p-isocyanatophenyl)thiophosphate in ethyl acetate (Desmodu® RFE, product of Bayer MaterialScience AG, Leverkusen, Germany) were initially introduced into a 500 ml round-bottomed flask and heated to 60° C. Thereafter, 42.37 g of 2-hydroxyethyl acrylate were added dropwise and the mixture was further kept at 60° C. until the isocyanate content had fallen below 0.1%. Thereafter, cooling was effected and the ethyl acetate was completely removed in vacuo. The product was obtained as a semiciystalline solid.

Preparation of the Polyol Component 1:

0.18 g of tin octanoate, 374.81 g of c-caprolactone and 374.81 g of a difunctional polytetrahydrofuranpolyetherpolyol (equivalent weight 500 g/mol OH) were initially introduced into a 1 1 flask and heated to 120° C. and kept at this temperature until the solids content (proportion of nonvolatile constituents) was 99.5% by weight or higher. Thereafter, cooling was effected and the product was obtained as a waxy solid.

Preparation of the Polyol Component 2:

0.25 g of tin octanoate, 374.81 g of ε-caprolactone and 141.51 g of Baysilon OFOH 502 6% (a hydroxyalkyl-functional (α,ω-carbinol) polydimethylsiloxane) were initially introduced into a 1 l flask and heated to 150° C. and kept at this temperature until the solids content (proportion of nonvolatile constituents) was 99.5% by weight or higher. Thereafter, cooling was effected and the product was obtained as a waxy solid.

Method for Determining DE and Δn of Holographic Formulations:

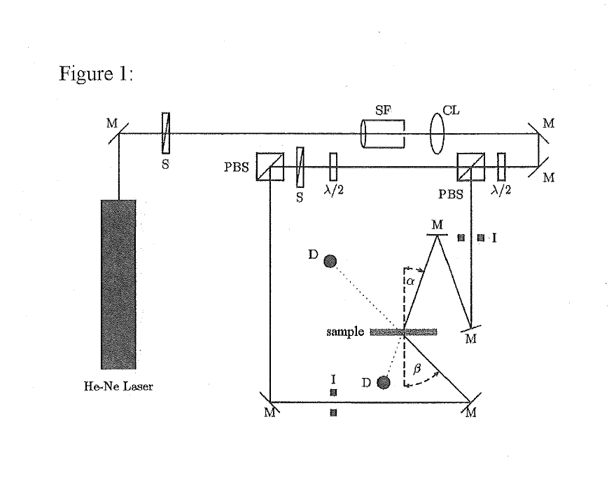

The media produced were tested with regard to their holographic properties DE and Δn by means of a measuring arrangement according to FIG. 1, as follows:

FIG. 1: Geometry of a holographic media tester at λ=633 nm (He—Ne laser) for writing a reflection hologram: M=mirror, S=shutter, SF=spatial filter, CL=collimator lens, λ/2=λ/2 plate, PBS=polarization-sensitive beam splitter, D=detector, I=iris diaphragm, α=21.8° and β=41.8° are the angles of incidence for the coherent beams, measured outside the sample (outside the medium).

The beam on He—Ne laser (emission wavelength 633 nm) was converted with the aid of the spatial filter (SF) and together with the collimation lens (CL) into a parallel homogeneous beam. The final cross sections of the signal and reference beam are established by the iris diaphragms (I). The diameter of the iris diaphragm opening is 0.4 cm. The polarization-dependent beam splitters (PSB) split the laser beam into two coherent equipolarized beams. Via the λ/2 plates, the power of the reference beam was adjusted of 0.5 mW and the power of the signal beam to 0.65 mW. The powers were determined using the semiconductor detectors (D) with sample removed. The angle of incidence (α) of the reference beam is 21.8° and the angle of incidence (β) of the signal beam is 41.8°. At the location of the sample (medium), the interference field of the two overlapping beams produced a grating of light and dark strips which are perpendicular to the angle bisectors of the two beams incident on the sample (reflection hologram). The strip spacing A, also known as grating period, in the medium is ˜225 mu (refractive index of the medium assumed to be ˜1.504).

Holograms were written into the medium in the following manner:
Both shutters (S) are opened for the exposure time t.
Thereafter, with shutters (S) closed, the medium was allowed a time of 5 minutes for diffusion of the still unpolymerized writing monomers.

The holograms written were now read in the following manner. The shutter of the signal beam remained closed. The shutter of the reference beam was opened. The iris diaphragm of the reference beam was closed to a diameter of <1 mm. This ensured that the beam was always completely in the previously written hologram for all angles (Ω) of rotation of the medium. The turntable, under computer control, covered the angle range from Ω=0° to Ω=20° with an angle step width of 0.05°. At each angle Ω approached, the powers of the beam transmitted in the zeroth order were measured by means of the corresponding detector D and the powers of the beam diffracted in the first order were measured by means of the detector D. The diffraction efficiency η was obtained at each angle Ω approached as the quotient of:

$$η = \frac{{P}_{D}}{{P}_{D} + {P}_{T}}$$

P_{D} is the power in the detector of the diffracted beam and P_{T} is the power in the detector of the transmitted beam.

By means of the method described above, the Bragg curve (it describes the diffraction efficiency η as a function of the angle Ω of rotation of the written hologram) was measured and was stored in a computer. In addition, the intensity transmitted in the zeroth order was also plotted against the angle Ω of rotation and stored in a computer.

The maximum diffraction efficiency (DE=ηₘₐₓ) of the hologram, i.e. its peak value, was determined. It may have been necessary for this purpose to change the position of the detector of the diffracted beam in order to determine this maximum value.

The refractive index contrast Δn and the thickness d of the photopolymer layer were now determined by means of the coupled wave theory (cf. H. Kogelnik, The Bell System Technical Journal, Volume 48, November 1969, Number 9, page 2909-page 2947) from the measured Bragg curve and the variation of the transmitted intensity as a function of angle. The method is described below:

According to Kogelnik, the following is true for the Bragg curve η(Ω) of a reflection hologram:

$$η = \frac{1}{1 + \frac{1 - {( χ / Φ )}^{2}}{{sinh}^{2} ( \sqrt{{Φ}^{2} - {χ}^{2}} )}}$$

with:

$$Φ = \frac{π \cdot Δ n \cdot d}{λ \cdot \sqrt{cos ( {α}^{′} ) \cdot cos ( {α}^{′} - 2 ψ )}}$$

$$χ = Δ θ \cdot \frac{2 π \cdot sin ( {α}^{′} - ψ )}{Λ \cdot cos ( {α}^{′} - 2 ψ )} \cdot \frac{d}{2}$$

$$ψ = \frac{{β}^{′} - {α}^{′}}{2}$$

$$Λ = \frac{λ}{2 \cdot n \cdot cos ( ψ - {α}^{′} )}$$

$$n \cdot sin ( {α}^{′} ) = sin ( α ) , n \cdot sin ( {β}^{′} ) = sin ( β )$$

$$Δ θ = - Δ Ω \cdot \sqrt{\frac{1 - {sin}^{2 } ( α )}{{n}^{2} - {sin}^{2} ( α )}}$$

Φ is the grating thickness, χ is the detuning parameter and ψ is the angle of tilt of the refractive index grating which was written. α′ and β′ correspond to the angles α and β during writing of the hologram, but measured in the medium. Δθ is the angle detuning measured in the medium, i.e. the deviation from the angle α′. ΔΩ is the angle detuning measured outside the medium, i.e. the deviation from the angle α. n is the average refractive index of the photopolymer and was set at 1.504. λ is the wavelength of the laser light in vacuo.

The maximum diffraction efficiency (DE=ηₘₐₓ) is then obtained for χ=0, i.e. ΔΩ=0, as:

$$DE = {tanh}^{2} ( Φ ) = {tanh}^{2} ( \frac{π \cdot Δ n \cdot d}{λ \cdot \sqrt{cos ( {α}^{′} ) \cdot cos ( {α}^{′} - 2 ψ )}} )$$

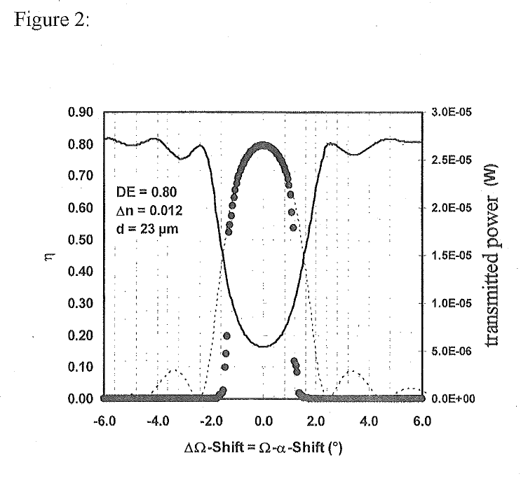

The measured data of the diffraction efficiency, the theoretical Bragg curve and the transmitted intensity are shown in FIG. 2 plotted against the centered angle of rotation Ω-α shift. Since, owing to geometric shrinkage and the change in the average refractive index during the photopolymerization, the angle at which DE is measured deters from α, the x axis is centered around this shift. The shift is typically 0° to 2°.

Since DE is known, the shape of the theoretic Bragg curve according to Kogelnik is determined only by the thickness d of the photopolymer layer. Δn is subsequently corrected via DE for a given thickness d so that measurement and theory of DE always agree. d is now adapted until the angle positions of the first secondary minima of the theoretical Bragg curve agree with the angle positions of the first secondary maxima of the transmitted intensity and additionally the full width at half maximum (FWHM) for the theoretical Bragg curve and the transmitted intensity agree.

Since the direction in which a reflection hologram concomitantly rotates on reconstruction by means of a Ω scan, but the detector for the diffracted light can detect only a finite angle range, the Bragg curve of broad holograms (small d) is not completely detected in an Ω scan, but only the central region, with suitable detector positioning. That shape of the transmitted intensity which is complementary to the Bragg curve is therefore additionally used for adapting the layer thickness d.

FIG. 2: Plot of the Bragg curve η according to Kogelnik (dashed line), of the measured diffraction efficiency (solid circles) and of the transmitted power (black solid line) against the angle detuning ΔΩ. Since, owing to geometric shrinkage and the change of the average refractive index during the photopolymerization, the angle at which DE is measured differs from α, the x axis is centered around this shift. The shift is typically 0° to 2°.

For a formulation, this procedure was possibly repeated several times for different exposure times t on different media in order to determine the average energy dose of the incident laser beam at which DE reaches the saturation value during writing of the hologram. The average energy dose E is obtained as follows from the powers of the two part-beams coordinated with the angles α and β (P_{α}=0.50 mW and P_{β}=0.67 mW), the exposure time t and the diameter of the iris diaphragm (0.4 cm):

$$E ( mJ / {cm}^{2} ) = \frac{2 \cdot ⌊ {P}_{α} + {P}_{β} ⌋ \cdot t ( s )}{π \cdot {0.4}^{2} {cm}^{2}}$$

The powers of the part-beams were adapted so that the same power density is achieved in the medium at the angles α and β used.

Method for Determining the Contact Angle and the Total Surface Tension:

A contact angle measurement was carried out with polar and nonpolar measuring liquids whose surface tension (polar and nonpolar fraction) is known. According to Owens and Wendt (D. K. Owens and R. C. Wendt, J. Appl. Polym, Sci. 13 (1969), pp. 1741-1747), the nonpolar and polar fraction of the solid-state surface tension to be determined can be calculated therefrom.

### Example 1

Exemplary Preparation of the Isocyanate-Reactive Component (Parts B and C According to the Invention):

9.05 g of the polyol component I prepared as described above were mixed with 3.75 g of urethane acrylate from Example 1 and 0.525 g of N-ethylpyrrolidone at 50° C. so that a clear solution was obtained.

Exemplary Preparation of the Isocyanate-Reactive Component (Parts B and C), Including Catalyst (F):

9.05 g of the polyol component 2 prepared as described above were mixed with 3.75 g of urethane acrylate from Example 1, 0.003 g of Fomrez UL 28 (urethanization catalyst, commercial product from Momentive Performance Chemicals, Wilton, Conn., USA) and 0.525 g of N-ethylpyrrolidone at 50° C. so that a clear solution was obtained.

Results from the measurement of the contact angle:

| | Total |
|---|---|
| | surface |
| | tension |
| Sample | [mN/m] |
| PC (Makrofol ® DE 1-1, 175 μm) cast film, commercial | 44.4 |
| product from Bayer MaterialScience AG, Leverkusen, Germany) | |
| PC (Pokalon OG 461, 30 μm) cast film, commercial product | 42.1 |
| from LOFO High Tech Film GmbH, Weil am Rhein, Germany) | |
| CTA (Tacphan P913 GL, 80 μm) cast film, commercial product | 46.2 |
| from LOFO High Tech Film GmbH, Weil am Rhein, Germany | |
| PET (Hostaphan GN 36 4600, 36 μm) cast film, commercial | 48.3 |
| product from Mitsubishi Polyester Film GmbH, Wiesbaden, | |
| Germany | |
| Isocyanate-reactive component (parts B and C) | 37 |
| Isocyanate-reactive component (parts B and C) including | 20 |
| catalyst (F) | |

The total surface tension value obtained for the isocyanate-reactive component (parts B and C) and the isocyanate-reactive component (parts B and C) including catalyst (F) in the experiment described above is less than the surface tension of each of the four selected substrates (part I of the holographic recording medium). Consequently, the preconditions for a good surface quality of the coating are fulfilled. This leads to transparent films which are usable in the entire visible range and can be used as a photopolymer for the representation of high-contrast holograms in the context of the above description.

### Example 2

Production of the holographic media based on photopolymer formulation with photoinitiator for determining the performance parameters DE and Δn:

Starting materials used for the photopolymer:

Polymer matrix component A: Desmodur® XP 2599, an experimental product of Bayer MaterialScience AG, Leverkusen, DE, fill allophanate of hexane diisocyanate on difunctional polypropylene oxide having a number-average molar mass of 200 g/mol, NCO content: 5.6-6.4%. Component B: difunctional polypropylene oxide having a number-average molar mass of 4000 g/mol, commercial product of Bayer MaterialScience AG, Leverkusen, Germany.

Writing monomer (component C): 25% proportion by weight.

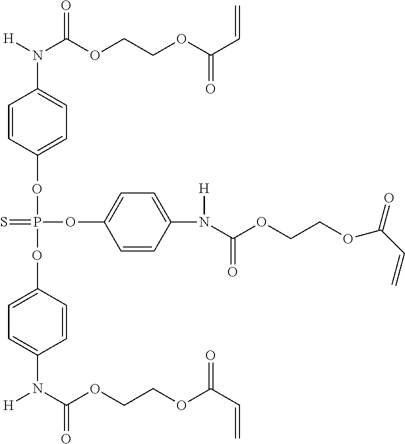

Photoinitiator (component D): New methylene blue 0.10% with CGI 909 (experimental product of Ciba Inc., Basel, Switzerland) 1%, both dissolved in N-ethylpyrrolidone, proportion of N-ethylpyrrolidone 3.5%

Catalyst used (component F): Fomrez® UL28 0.05%, urethanization catalyst, dimethylbis[(1-oxoneodecl)oxy]stannane, commercial product from Momentive Performance Chemicals, Wilton, Conn., USA (used as 10% strength solution in N-ethylpyrrolidone)

Levelling agent: Byk® 310 (silicone-based surface additive from BYK-Chemie GmbH, Wesel, 25% strength solution in xylene) 0.3%

Substrate: Makrofol DE 1-1 CC 175 μm (Bayer MaterialScience AG, Leverkusen, Germany) with PE CHX 173 back lamination (Bischoff & Klein, Germany)

Top laminating film: PE 40 μm smooth. (Bischoff & Klein, Germany)

For the production of the holographic media, the component B), the component C) (which may already have been predissolved in the component B)) and optionally the additives are dissolved in the isocyanate-reactive component B), optionally at 60° C., in the dark. Thereafter, the isocyanate component A) is added and mixing is effected again in the Speedmixer for 1 minute. Subsequently, a solution of the component C) is added and mixing is effected in the Speedmixer again for 1 minute. The mixture obtained is applied to the Makrofol substrate in a coating tool (knifecoater). The knifecoating method is characterized by: knifecoater nip 60 μm, web speed 0.7 m/min. The curing of the PU formulation is effected in the dryer at 80-100° C. for 10-15 min.

By measuring the contact angle of the composition, a total surface tension of 23.7 mN/m was determined.

For the holographic medium obtained in Example 2, a Δn of 0.012 was obtained for the average energy dose E=18 mJ/cm². The diffraction efficiency was 98% and the layer thickness d was 55 μm.

1-12. (canceled)

13. A medium suitable for recording holograms, comprising:
I) as a carrier, a stratum of a transparent material which is transparent to light in the visible spectral range, having a transmission of greater than 85% in the wavelength range of 400 to 780 nm, and is coated on one or both sides; and
II) at least one photopolymer stratum applied to the carrier I) and based on polyurethane compositions, comprising
A) a polyisocyanate component,
B) an isocyanate-reactive component,
C) compounds which have groups reacting under the action of actinic radiation with ethylenically unsaturated compounds with polymerization (radiation-curing groups) and which themselves are free of NCO groups,
D) photoinitiators, and
E) free radical stabilizers.

14. The medium according to claim 13, wherein the carrier I) is based on polycarbonate, polyethylene terephthalate and/or cellulose triacetate or glass as materials.

15. The medium according to claim 13, wherein the carrier I) is based on duplex or triplex films as materials or material composites.

16. The medium according to claim 13, wherein the carrier I) has a birefringence, expressed via the mean optical retardation, of less than 1000 nm.

17. The medium according to claim 13, wherein the carrier I) is treated on one or both sides to make it nontacky, antistatic, water repellent, hydrophilic, scratch-resistant, reflective or anti reflective.

18. The medium according to claim 13, wherein the at least one photopolymer stratum II) have a total layer thickness, based on all photopolymer strata applied in layer II) of not more than 200 μm.

19. The medium according to claim 13, wherein the polyurethane compositions of the photopolymer stratum II) have a total surface tension which is less than that of the carrier I), including any coatings.

20. The medium according to claim 13, wherein the polyurethane compositions in component C) comprise one or more compounds of the formulae (I) to (III): 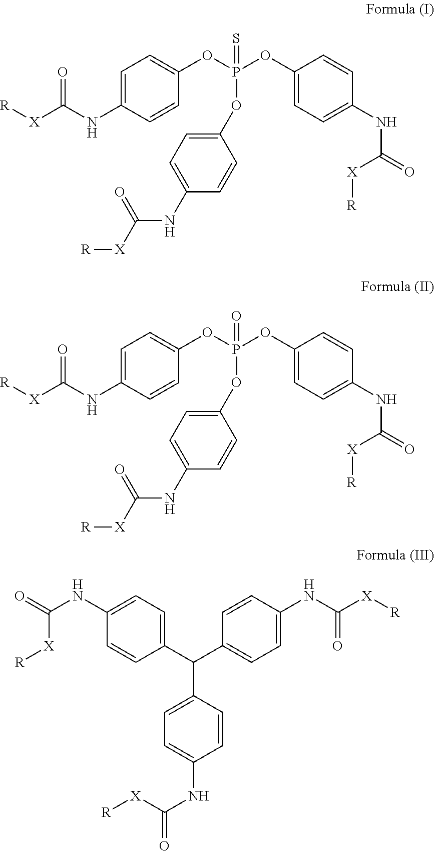
in which
R, independently of one another, are in each case a radiation-curable group and
X, independently of one another, are in each case a single bond between R and C═O or a linear, branched or cyclic hydrocarbon radical.

21. The medium according to claim 20, wherein X as the linear, branched or cyclic hydrocarbon radical contains heteroatoms.

22. The medium according to claim 20, wherein X as the linear, branched or cyclic hydrocarbon radical is substituted by functional groups.

23. The medium according to claim 13, further comprising one or more cover layers Ill) on the photopolymer stratum II).

24. The medium according to claim 13, wherein the at least one photopolymer stratum further comprises:
F) catalysts.

25. The medium according to claim 13, wherein the at least one photopolymer stratum further comprises:
G) auxiliaries and additives.

26. A method for the production of a medium suitable for recording holograms according to claim 13, in which one or more photopolymer strata II) are applied to a carrier I) and cured.

27. A method for recording holograms, in which a medium according to claim 13 is exposed by means of a laser beam.
